(19) United States
(12) Patent Application Publication
(10) Pub. No.: US 2006/0139861 A1
(43) Pub. Date: Jun. 29, 2006

(54) Portable accessory device having a port interface used to provide multiple integrated functionalities

(75) Inventors: Michael Krieger, Miami Beach, FL (US); Kevin Ellsworth, Hollywood, FL (US)

Correspondence Address: VECTOR PRODUCTS, INC.;ROBERT POWELL, P.O. BOX 34385, c/o VENABLE LLP, WASHINGTON, DC, 20043-9998, US

(73) Assignee: Vector Products, Inc., Ft. Lauderdale, FL (US)

(21) Appl. No.: 11/239,384

(22) Filed: Sep. 30, 2005

Related U.S. Application Data
(60) Provisional application No. 60/614,388, filed on Sep. 30, 2004.

(51) Int. Cl. H05K 5/00

(52) U.S. Cl. 361/679

(57) ABSTRACT

A portable accessory device, comprises a resource device circuit, such as a storage device, having a port interface circuit that interfaces with an external device via a port. The port interface circuit provides an electrical power source via the external device for powering the resource device. A battery powers at least one user activated functionality of the accessory device, such as one provided by a light source. A housing encloses the resource device circuit, the port interface circuit and the battery to provide a plurality of integrated functionalities for the accessory device.

### RELATED APPLICATIONS

This application claims priority to U.S. Provisional Patent Appln. No. 60/614,388, which was filed on Sep. 30, 2004, and is hereby incorporated by reference.

### FIELD OF THE INVENTION

The present invention generally relates to accessory devices and more particularly to a portable accessory device having a port interface that is used to provide multiple integrated functionalities.

### DESCRIPTION OF THE PRIOR ART

Accessory devices that perform multiple functions are known. For example, portable accessories offer multiple functionality for accomplishing various tasks ranging from cutting an object by a knife or scissor, to turning screws by a screw drive, to opening bottles by bottle openers.

With recent proliferation of portable computing, portable storage devices have been developed for exchanging data with an external device (e.g., a PC or a media player) through a standard port interface. For example, data can be stored and transported in a small flash memory device that is equipped with a known Universal Serial Bus (USB) port that interfaces with a corresponding port on the external device, for data exchange. In fact, some portable accessories have already been equipped with a flash memory USB device.

The above mentioned memory devices have also been used to store music and other multimedia content to be played on a portable media player accessory device. In one arrangement, a USB equipped flash memory can be inserted into a battery powered MP3 player for storage of music or other content. In another, MP3 player watches have been equipped with flash memory, powered by the watch battery. Such memory devices have also been used as a single accessory device equipped with one or more light emitting devices (LEDs) that provide visual indication of functional modes of the storage device (e.g., storing data or retrieving data modes).

USB battery charging is known. Besides directly powering USB devices, Dallas Semiconductor discloses the use of MAXIM chips, e.g., MAX 1692 and MAX 1722, MAX 1874, MAX 1555, with USB power to perform battery charging. Since many portable devices, like MP3 players and PDAs, exchange information with PCs, device convenience is significantly enhanced if battery charging and data exchange take place simultaneously and over one cable. Combining USB and battery-powered functionality gives rise to a whole range of “untethered” devices, such as removable web cameras, that operate while connected to a PC or not.

At times, it is desired to attach the storage device to the computer in low light or dark conditions, for example, when attempting to connect the storage device to the computer port in a dark room. In one prior art arrangement, a pocket accessory includes a body having a hinge about which a flash memory USB device swivels. The pocket accessory is equipped with a switch activated light source that is powered by a battery that is disposed in a housing separate from the housing of the flash memory USB device. It is, however, desired to use the USB port to improve functionalities of the portable accessory devices.

### SUMMARY OF THE INVENTION

Briefly, according to the present invention, a portable accessory device, comprises a resource device circuit, such as a storage device, e.g., flash memory, having a port interface circuit that interfaces with an external device via a port. Other examples of such a resource device comprise a device having audio, imaging, multi-media, or video capability. The port interface circuit provides an electrical power source via the external device for powering the resource device. A battery powers at least one user activated functionality of the accessory device, such as one provided by a light source, e.g., an LED for lighting functionality or a laser diode device for pointing functionality. A housing encloses the resource device circuit, the port interface circuit and the battery to provide a plurality of integrated functionalities for the accessory device.

According to one of the more detailed features of the invention, a charge circuit that is powered by the electrical power source of the port interface is used for charging the battery.

According to another more detailed feature of the invention, the plurality of integrated functionalities comprise at least one of data storage, user-activated lighting, or user activated pointing functionalities, whereby the light source functionality is provided via a user activated light switch enclosed within the enclosure. According to yet another more detailed feature of the invention, the battery is used to power the external device.

According to another aspect of the present invention, an accessory system comprises a battery powered portable accessory device that detachably interfaces with an external device. The portable accessory device has a first port interface for receiving electrical power for charging one or more batteries that power a user activated functionality, such as a light source. The external device has a second port interface that is complementary to the first port interface and provides the electrical power for charging the batteries. The housing of the external device comprises a groove, which is properly aligned with the second port interface for facilitating a slideable engagement and disengagement between the portable accessory device and the portable accessory device via the complementary first and second port interfaces.

### BRIEF DESCRIPTION OF THE DRAWINGS

FIG. 1 shows a diagram of a portable accessory device according to one embodiment of the present invention.

FIG. 2 shows another diagram of the portable accessory device of FIG. 1.

FIG. 3 shows a diagram of another portable accessory device as a stand alone unit.

FIG. 4 shows a diagram of the portable accessory device of FIG. 3 detachably sliding within a grooved housing of an external device.

FIG. 5 shows a diagram of the portable accessory device of FIG. 3 engaged with the external device of FIG. 4.

FIG. 6 shows an exemplary schematic block diagram of the portable accessory device of the present invention.

### DESCRIPTION OF THE INVENTION

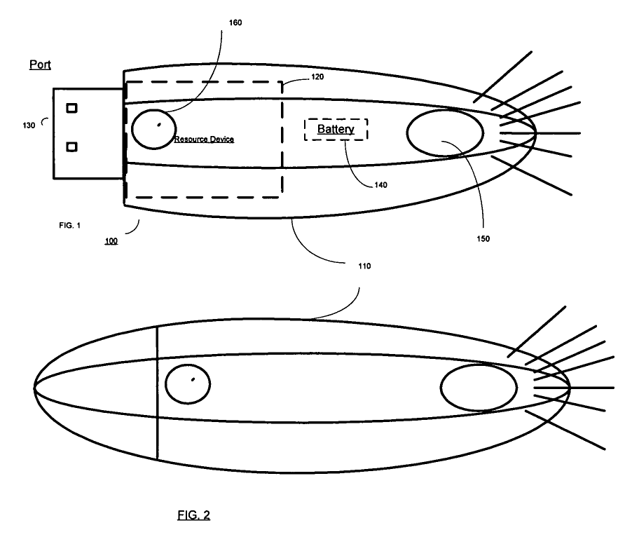

FIG. 1 shows a diagram of a portable accessory device 100 according to one exemplary embodiment of the present invention. The accessory device 100 is a battery powered accessory device having a housing 110 that encloses a resource device 120 having a port interface 130 for interfacing with an external device (not shown). In an exemplary embodiment, the resource device 120 is a storage device that can be used for data exchange via the port interface 130. Other examples of such resource device comprise a device having audio, imaging, multi-media, or video capability. The housing 110 also encloses a battery 140 that powers a user-activated functionality. In an exemplary embodiment, the user activated functionality is lighting as provided by a light source 150 that is powered by the battery 140. In this way, the portable accessory device of the invention provides integrated storage and light source functionalities. As such, unlike the above-described prior art approach that uses separate housings for enclosing the battery and the storage device, the accessory device of the present invention uses a single housing that integrates the multiple functionalities within the same enclosure. For example, the housing 110 can enclose the resource device 120, the port interface 130, and the battery 140, and the light source 150 to provide integrated data storage and light source functionalities.

As sown in FIG. 2, the exemplary accessory device of the present invention can be used as a portable data storage and a flash light that can be turned on and off by a user by activating a light switch 160, while the functionalities of the accessory device are enhanced by close interface of the battery, storage device and port interface in the same housing. For example, when trying to interface the USB ports of the data storage device with an external device (e.g., a computer or a media player) in dark conditions, the user can activate the switch to turn the light source on as necessary.

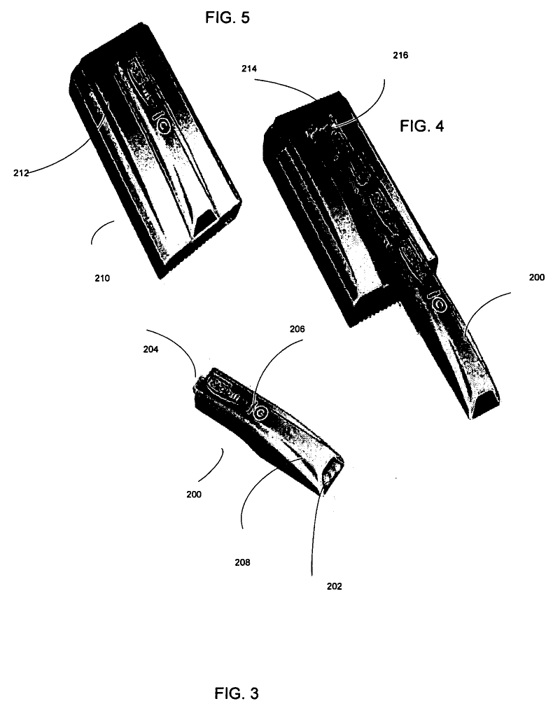

FIG. 3 shows a portable accessory device 200 according to another exemplary embodiment of the present invention. In this exemplary embodiment, the portable accessory device 200 is a battery powered flash light unit. The portable accessory device 200 includes one or more rechargeable batteries that power one or more LEDs 202 functioning as one or more light sources. The portable accessory device 200 can function either as a stand alone flash light unit or function in combination with other types of resource devices, such as storage devices, media players (e.g., audio, video, text, image players), media recorders, etc. A port interface circuit 204, such as a male USB interface, interfaces the resource device with an external device 210, as shown in FIG. 4. Via a complementary interface port, e.g., a female USB interface port, the external device provides electrical signals, including electrical power signals for charging batteries of the portable accessory device. The port interfaces used in the present invention can be any suitable port interface that provides or receives electrical power. Examples of such port interfaces include USB or FireWire ports. In FIG. 3, the port interface of the portable accessory device is shown as a male USB interface 204. The one or more batteries, which are disposed in the housing 208 of the portable accessory device 200, power one or more user activated functionalities. Such user activated functionalities can include light source functionality, e.g., turning the light source off and on, or media player functionality, e.g., playing media, controlling audio volume, fast forward, rewind, media recording, etc. A switch or button or any other suitable control mechanism 206 can be used for activating the user activated functionality of the portable accessory device 200. The housing 208 encloses the LED circuits, resource device circuits, if any, port interface circuits, and the one or more batteries to provide a plurality of integrated functionalities for the accessory device.

As shown in FIG. 4, the portable accessory device 200 interfaces with the external device 210 via a sliding arrangement. In the exemplary embodiment, the external device 210 has a slim housing 212 for enclosing power circuits and a port interface 214, e.g. a female USB interface, that is used for exchange of electrical signals with peripheral devices, such as the exemplary possible accessory device 200, which has the male USB interface 204, as shown in FIG. 3. In addition, either the external device 210 or the portable accessory device 200 can have a USB host functionality for complementing each others functionality. For example, the portable accessory device 200 can include a USB storage device functionality for storage of media files and the external device 210 can include a media player functionality for reading a properly formatted media files, via its female USB port, from the USB storage device of the accessory device 200 and playing the media file based on its format, e.g., audio, video, text, image format. In one embodiment, the portable accessory device can include an FM transmitter for transmitting audio played by the media player to an external receiver over a selected frequency channel. Conversely, the external device 210 can include a USB storage functionality and the portable accessory device 200 can have a media player functionality. Under this arrangement, the properly formatted media files stored in the USB storage of the external device could be read and played by the portable accessory device 200. Thus, the electrical signals exchanged between the portable accessory device 200 and the external device 210 can comprise powering and/or charging signals (e.g., 5 volts), information signals (e.g., data bits), media signals (e.g., audio, video, text, image), etc.

A groove 216 disposed on one side of the housing, e.g., top side, of the external device accommodates the slideable engagement of the portable accessory device 200 with the external device 210. As shown in FIG. 4, the groove 216 is positioned on the external device housing to be aligned with the port interface 214 of the external device to provide a slideable electrical engagement and disengagement facility between the portable accessory device and the external device via the complementary port interfaces 204 and 214. In this way, by properly alignment with the groove 216, the portable accessory device 200 can slide on the grooved side of the housing 212 to be detachably coupled with the external device 210. Complimentary port interfaces, i.e., the male USB port interface 204 and female port interface 214 provide for detachable engagement of the portable accessory device 200 and external device 210. Upon engagement by sliding the portable accessory device 200 within the groove 216, the power circuitry disposed in the external device 210 can provide the necessary electrical signals, including signals that charge the batteries of the portable accessory device, vis the complimentary port interface, as shown in FIG. 5. Once charged, the portable accessory device 200 can be detached from the external device for use as a stand alone device.

As shown in FIGS. 3, 4 and 5, one aspect of the present invention relates to an accessory system. The accessory system comprises the battery powered portable accessory device 200, which has a first port interface, e.g., the male USB port 204, for receiving electrical power for charging one or more batteries that power a user activated functionality, e.g., the light source LEDs 202. The external device 210 has a second port interface, e.g., the female USB port 214, that is complementary to the first port interface and provide the electrical power for charging the batteries. The housing 212 of the external device 210 comprises the groove 216, which is properly aligned with the second port interface for facilitating a slideable engagement and disengagement between the portable accessory device and the portable accessory device 300 via the complementary first and second port interfaces.

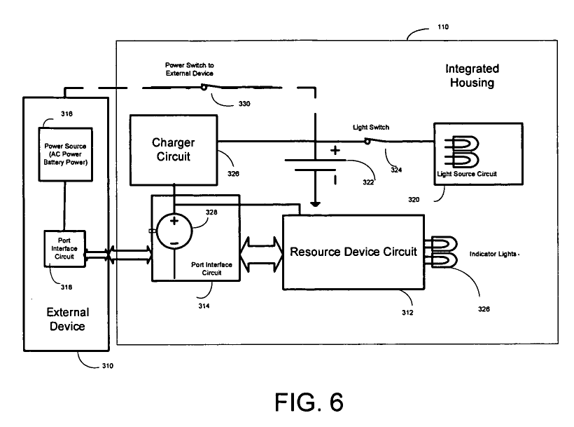

FIG. 6 shows a block diagram of a portable accessory device 300 according to the present invention, which interfaces with an external device 310. Among other things, the portable accessory device 100 includes a resource device circuit 312 and a port interface circuit 314 that allows for sharing resources with the external device. Examples of the resource device include a storage device, an audio device, such as MP3 devices, a multi-media device, an imaging device, or a video, such as MPEG device. Examples of the port interface circuit are those well defined by the USB specification or other similar port interfaces.

For example, if a storage device is used as the resource device, the portable accessory device 100 can be used for exchange of data with the external device 310. Such data exchange could include receiving data from the external device 310 for storage in the resource device circuit 312 or providing stored data in the resource device circuit 312 to be retrieved by the external device 310. In the exemplary embodiment of the present invention, the resource device circuit 312 can be any one of known memory devices, e.g., flash memory, etc, that is accessible by a port interface for data storage or retrieval.

The external device 310 includes a power source 316 that is used for providing electrical power to a port interface circuit 318 in the external device. The external device 310 can comprise a wide variety of devices providing port interface capability with the portable accessory device 100 of the present invention. For example, the external device 310 can be a computing device, a media player device or any device that provides a suitable port interface with the portable accessory device 100. The port interface used by the invention can be any suitable standardized port, such as USB, etc.

The USB port interface circuit provides an electrical power supply via the external device for powering the resource device. Thus, when the portable accessory device 100 is connected to the external device 310, the port interface circuit 314 in the accessory device is electrically coupled to the corresponding port interface circuit 318 in the external device 310 such that data can be exchanged or other resources can be shared between the external device 310 and the accessory device 100.

As shown in FIG. 6, a light source circuit 320 is powered by a battery 322 via a switch 324 that is used to activate or deactivate the light source. The light source circuit 320 can comprise any suitable source, including one or more LEDs and lenses that provide the desired lighting under various lighting conditions. If necessary, the light source circuit 320 can provide light with suitable color and intensity to suit various applications. In another embodiment, the light source circuit 320 comprises a laser diode light source that allows the portable accessory device of the present invention to be used as a pointing device. The portable accessory device 100 of the present invention may be further equipped with mode indication LEDs 320 to provide visual signal for various operating modes of the resource device.

The battery 322 can be any commercially available battery that provides sufficient energy for powering the user activated functionality of the portable accessory device, including the light source circuit 320. In one embodiment of the present invention, the accessory device powers the light source by a rechargeable battery. According to this embodiment, the accessory device includes a charger circuit 326 that provides re-charge energy via a power source 328 that is provided by the port interface circuit 314.

Therefore, enclosing the battery in the same housing as the resource device facilitates interfacing the battery with the port interface for recharging the battery that powers the user activated functionality, e.g., the light source. Thus, in the disclosed exemplary embodiment, the portable accessory device 300 provides multiple functionalities, e.g., data storage and lighting (or pointing) by enclosing the means that provide these functionalities along with the port interface in a single housing. As is known, USB interface provides a power sources for powering daisy chained USB devices. Thus, this embodiment of the invention can use the power source provided through the USB port to charge the battery power of the light source.

In another embodiment, the data storage accessory device of the present invention is interfaced with a multimedia content player such as an MP player. Under this arrangement, the battery 322 of the portable accessory device 300 can be used to power the media player via a switch 330.

The invention has been described in detail with respect to referred embodiments, and it will now be apparent from the foregoing to those skilled in the art, that changes and modifications may be made without departing from the invention in its broader aspects, and the invention, therefore, as defined in the appended claims, is intended to cover all such changes and modifications that fall within the true spirit of the invention.

1. A portable accessory device, comprising
a resource device circuit;
a port interface circuit that interfaces the resource device with an external device via a port, said port interface circuit providing an electrical power supply via the external device for powering the resource device;
a battery that powers at least one user activated functionality of the accessory device; and
a housing that encloses the resource device circuit, the port interface circuit and the battery to provide a plurality of integrated functionalities for the accessory device.

2. The portable accessory device of claim 1, further including a charger circuit that is powered by the electrical power supply of the port interface for charging the battery.

3. The portable accessory device of claim 1, wherein the at least one user activated functionality comprises at least one light source.

4. The portable accessory device of claim 3, wherein the light source comprises at least one of an LED or a laser diode device.

5. The portable accessory device of claim 3, wherein the resource device comprises at least one of a storage device, an audio device, a multi-media device, an imaging device or a video device.

6. The portable accessory device of claim 1, wherein said plurality of integrated functionalities comprise at least one of a data storage functionality, a lighting functionality or a pointing functionality.

7. The portable accessory device of claim 6, further comprising a light switch enclosed within the housing for providing user activated lighting functionality.

8. The portable accessory device of claim 1, wherein the resource device circuit comprises a flash memory.

9. The portable accessory device of claim 1, wherein the port interface circuit is configured to the battery to power the external device.

10. The portable accessory device of claim 1, wherein the battery is coupled to power the external device.

11. The portable accessory device of claim 1, wherein the port interface circuit comprises a USB interface circuit.

12. An accessory system, comprising:
a portable accessory device having a first port interface for receiving electrical power for charging one or more batteries that power a user activated functionality of the portable accessory device; and
an external device having a second port interface that is complementary to the first port interface and a housing that comprises a groove aligned with the second port interface for facilitating a slideable engagement and disengagement between the external device and the battery powered portable accessory device via the complementary first and second port interfaces.

13. The accessory system of claim 11, wherein the user activated functionality comprises at least one light source.

14. The accessory system of claim 12, wherein the light source comprises at least one of an LED or a laser diode device.

15. The accessory system of claim 11, wherein the portable accessory device further comprises a resource device.

16. The accessory system of claim 11, wherein the resource device comprises at least one of a storage device, an FM transmitter or a media player.

17. The accessory system of claim 11, wherein the user activated functionality comprise at least one of a data storage functionality, a media player functionality, a lighting functionality or a pointing functionality.

18. The accessory system of claim 11 further comprising a light switch enclosed within the housing for providing user activated lighting functionality.

19. The accessory system of claim 14, wherein the resource device comprises a flash memory.

20. The accessory system of claim 11, wherein the one or more batteries are used to power the external device.

21. The accessory system of claim 11, wherein the first and second port interfaces comprise complementary USB port interfaces.
